(19) United States
(12) Patent Application Publication
(10) Pub. No.: US 2014/0030874 A1
(43) Pub. Date: Jan. 30, 2014

(54) METHOD FOR MANUFACTURING SILICON CARBIDE SUBSTRATE

(71) Applicant: Sumitomo Electric Industries, Ltd., Osaka (JP)

(72) Inventors: Tsubasa HONKE, Itami-shi (JP); Taro NISHIGUCHI, Itami-shi (JP); Tsutomu HORI, Itami-shi (JP)

(21) Appl. No.: 13/915,109

(22) Filed: Jun. 11, 2013

(30) Foreign Application Priority Data
Jul. 26, 2012 (JP) 2012-165789

(51) Int. Cl. H01L 21/02

(52) U.S. Cl. CPC H01L 21/02529
USPC 438/478

(57) ABSTRACT

A method for manufacturing a silicon carbide substrate includes the steps of: preparing a seed substrate made of silicon carbide; etching a main surface of the seed substrate prepared; obtaining an ingot by growing a silicon carbide single crystal film on a crystal growth surface formed by etching the main surface of the seed substrate;

and obtaining a silicon carbide substrate by cutting the ingot. The step of etching the seed substrate includes: a first etching step of removing silicon atoms, which form the silicon carbide, from an etching region using chlorine gas, the etching region being a region including the main surface of the seed substrate; and a second etching step of removing carbon atoms, which form the silicon carbide, from the etching region from which the silicon atoms have been removed, using oxygen gas.

### BACKGROUND OF THE INVENTION

1. Field of the Invention

The present invention relates to a method for manufacturing a silicon carbide substrate, more particularly, a method for manufacturing a silicon carbide substrate having high quality.

2. Description of the Background Art

In recent years, in order to achieve high breakdown voltage, low loss, and the like in a semiconductor device, silicon carbide has begun to be adopted as a material for the semiconductor device. Silicon carbide is a wide band gap semiconductor having a band gap larger than that of silicon, which has been conventionally widely used as a material for semiconductor devices. Hence, by adopting silicon carbide as a material for a semiconductor device, the semiconductor device can have a high breakdown voltage, reduced on-resistance, and the like.

In such a semiconductor device employing silicon carbide as its material, a substrate made of silicon carbide is used. The silicon carbide substrate can be obtained by, for example, cutting an ingot produced by growing a silicon carbide single crystal on a seed substrate by means of a sublimation recrystallizing method. In the sublimation recrystallizing method, when a damage layer such as a polishing flaw exists in a seed substrate's crystal growth surface on which a silicon carbide single crystal is to be grown, the damage layer will cause crystal defects in the silicon carbide single crystal, disadvantageously. To address this, as a method for removing such a damage layer in the crystal growth surface of the seed substrate, the following methods have been proposed. That is, Japanese Patent Laying-Open No. 2010-111540 (Patent Literature 1) proposes a method for etching the crystal growth surface of the seed substrate using an etching gas such as hydrogen gas. Japanese Patent Laying-Open No. 2009-256145 (Patent Literature 2) proposes a method for annealing the seed substrate under non-oxidizing gas atmosphere. Japanese Patent Laying-Open No. 2011-225392 (Patent Literature 3) proposes a method for forming a thin film, which contains silicon, on the crystal growth surface of the seed substrate. Japanese Patent Laying-Open No. 2008-115036 (Patent Literature 4) proposes a method for forming an etch pit for a surface terminal portion of a dislocation in the surface of the seed substrate. Japanese Patent Laying-Open No. 8-208398 (Patent Literature 5) proposes a method for forming an oxide film on the surface of the seed substrate. Japanese Patent Laying-Open No. 7-97299 (Patent Literature 6) proposes a method for etching the crystal growth surface of the seed substrate using molten potassium hydroxide.

Because each of the methods proposed in Patent Literature 1 to Patent Literature 5 is capable of removing only a small amount of a region including the crystal growth surface of the seed substrate, it is difficult to sufficiently remove the damage layer existing in the crystal growth surface. Meanwhile, in the method proposed in Patent Literature 6, the crystal growth surface of the seed substrate is not uniformly etched, so that it is difficult to sufficiently remove the damage layer from all over the crystal growth surface. Thus, the methods proposed in Patent Literature 1 to Patent Literature 6 are not capable of sufficiently removing the damage layer existing in the crystal growth surface of the seed substrate. Accordingly, it is difficult to manufacture a silicon carbide substrate having high quality.

### SUMMARY OF THE INVENTION

The present invention has been made in view of the foregoing problem, and has its object to provide a method for manufacturing a silicon carbide substrate having high quality.

A method for manufacturing a silicon carbide substrate in the present invention includes the steps of: preparing a seed substrate made of silicon carbide; etching one main surface of the seed substrate prepared; obtaining an ingot by growing a single crystal film, which is made of silicon carbide, on a crystal growth surface formed by etching the main surface of the seed substrate; and obtaining a silicon carbide substrate by cutting the ingot. The step of etching the seed substrate includes: a first etching step of removing silicon atoms, which form the silicon carbide, from an etching region using a gas including halogen atoms, the etching region being a region including the main surface of the seed substrate; and a second etching step of removing carbon atoms, which form the silicon carbide, from the etching region from which the silicon atoms have been removed, using an oxidizing gas.

In the method for manufacturing the silicon carbide substrate in the present invention, the main surface of the seed substrate is etched through the step including: the first etching step of removing the silicon atoms from the etching region including the main surface of the seed substrate; and the second etching step of removing the carbon atoms from the etching region from which the silicon atoms have been removed. Accordingly, an amount of etching the seed substrate is increased as compared with a conventional method for manufacturing a silicon carbide substrate, whereby the damage layer in the main surface of the seed substrate can be sufficiently removed even when the damage layer is thick. As a result, crystal defects can be suppressed from occurring in the single crystal film due to the damage layer. Thus, according to the method for manufacturing the silicon carbide substrate in the present invention, a silicon carbide substrate having high quality can be manufactured.

In the method for manufacturing the silicon carbide substrate, in the first etching step, the silicon atoms forming the silicon carbide may be removed while the carbon atoms forming the silicon carbide remain in the etching region. Accordingly, an amount of etching the seed substrate can be increased more securely.

In the method for manufacturing the silicon carbide substrate, in the first etching step, the silicon atoms forming the silicon carbide may be removed from the etching region using chlorine gas or hydrogen chloride gas. As such, in the above-described step, the chlorine gas or hydrogen chloride gas suitable for etching of the seed substrate made of silicon carbide can be employed suitably.

The method for manufacturing the silicon carbide substrate may further include the step of substituting the gas including the halogen atoms with an inert gas, after the first etching step and before the second etching step. In this way, a reactant of the silicon atoms and the gas including the halogen atoms can be suppressed from reacting with oxidizing gas.

In the method for manufacturing the silicon carbide substrate, the silicon carbide substrate obtained in the step of obtaining the silicon carbide substrate may have a diameter of 2 inches or more. Thus, the above-described method for manufacturing the silicon carbide substrate can be suitably employed in manufacturing of a silicon carbide substrate having a large diameter.

In the method for manufacturing the silicon carbide substrate, in the step of etching the seed substrate, the main surface of the seed substrate may be etched at a temperature of not less than 800° C. and not more than 1100° C. Thus, in the step, there can be employed a temperature condition under which the main surface of the seed substrate can be effectively etched.

In the method for manufacturing the silicon carbide substrate, in the step of etching the seed substrate, the main surface of the seed substrate may be etched at a pressure of not less than 1 Pa and less than 100 kPa. Thus, in the step, there can be employed a pressure condition under which the main surface of the seed substrate can be effectively etched.

In the method for manufacturing the silicon carbide substrate, the silicon carbide substrate obtained in the step of obtaining the silicon carbide substrate may have a dislocation density of 1×10⁴cm⁻² or less. In this way, a semiconductor device having higher quality can be manufactured using the silicon carbide substrate.

As apparent from the description above, according to the method for manufacturing the silicon carbide substrate in the present invention, a silicon carbide substrate having high quality can be manufactured.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a flowchart schematically showing a method for manufacturing a silicon carbide substrate.

FIG. 2 is a schematic view for illustrating the method for manufacturing the silicon carbide substrate.

FIG. 3 is a schematic view for illustrating the method for manufacturing the silicon carbide substrate.

FIG. 4 is a schematic view for illustrating the method for manufacturing the silicon carbide substrate.

FIG. 5 is a schematic view for illustrating the method for manufacturing the silicon carbide substrate.

FIG. 6 is a schematic view for illustrating the method for manufacturing the silicon carbide substrate.

FIG. 7 is a schematic view for illustrating the method for manufacturing the silicon carbide substrate.

FIG. 8 is a schematic view for illustrating the method for manufacturing the silicon carbide substrate.

FIG. 9 is a schematic view for illustrating the method for manufacturing the silicon carbide substrate.

FIG. 10 is a schematic view for illustrating the method for manufacturing the silicon carbide substrate.

### DESCRIPTION OF THE PREFERRED EMBODIMENTS

The following describes an embodiment of the present invention with reference to figures. It should be noted that in the below-mentioned figures, the same or corresponding portions are given the same reference characters and are not described repeatedly.

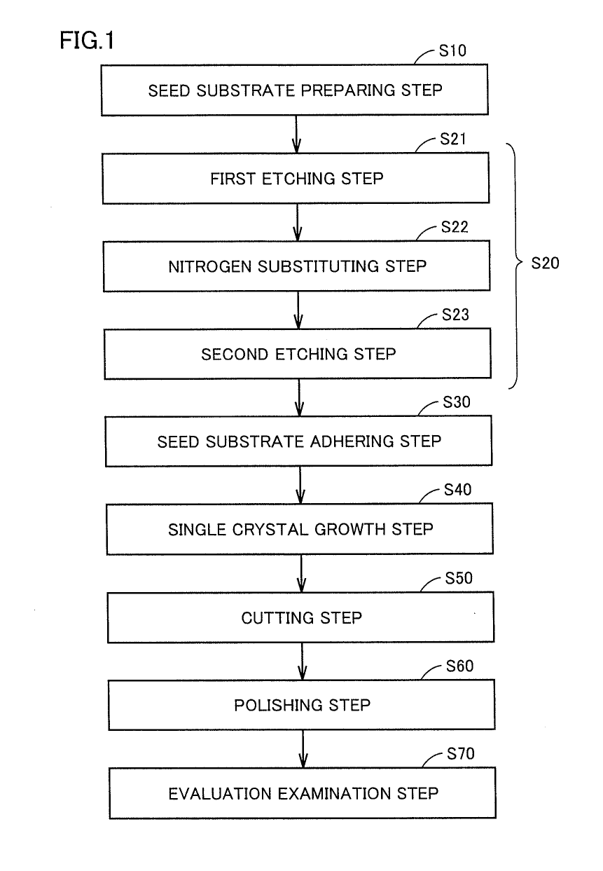

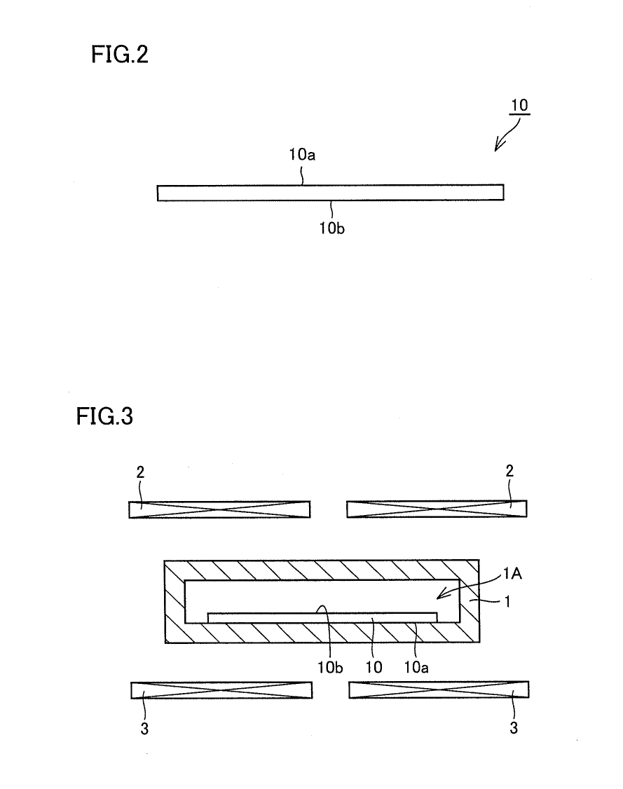

The following describes a method for manufacturing a silicon carbide substrate in one embodiment of the present invention. Referring to FIG. 1, as a step (S10), a seed substrate preparing step is first performed. In this step (S10), referring to FIG. 2, an ingot (not shown) formed of silicon carbide single crystal is first cut to prepare a seed substrate 10 having main surfaces 10a, 10b and made of silicon carbide. Seed substrate 10 has a shape of circular plate, and has a diameter of 2 inches or more, for example. By grinding main surfaces 10a, 10b of seed substrate 10, damage layers in main surfaces 10a, 10b are removed. Further, main surfaces 10a, 10b of seed substrate 10 may be further polished by means of mechanical polishing, or may be further polished by means of CMP (Chemical Mechanical Polishing).

Next, as a step (S20), an etching step is performed. In this step (S20), below-described steps (S21) to (S23) are performed, thereby etching one main surface 10b of seed substrate 10 prepared in step (S10).

First, as step (S21), a first etching step is performed. In this step (S21), referring to FIG. 3, seed substrate 10 is placed in an etching chamber 1A of a reaction tube 1 such that main surface 10b to be etched faces upward. Next, etching chamber 1A is vacuumed to a predetermined pressure. Next, while maintaining the vacuum state in etching chamber 1A, temperature in etching chamber 1A is increased to a temperature of not less than 800° C. and not more than 1100° C. using heaters 2, 3 disposed external to reaction tube 1.

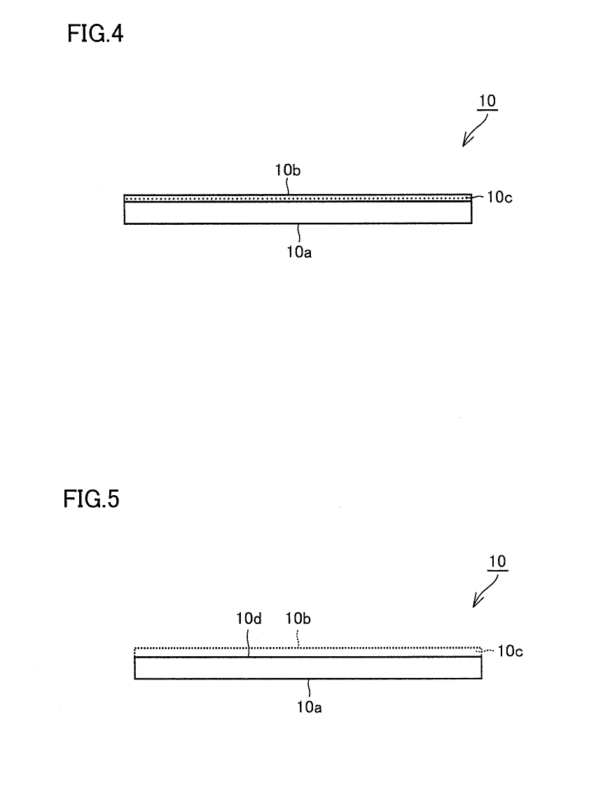

Next, chlorine (Cl₂) gas, which includes halogen atoms, is introduced into etching chamber 1A via a gas inlet (not shown) of reaction tube 1, and is exhausted from a gas outlet (not shown). Etching chamber 1A is set to have a pressure of not less than 1 Pa and less than 100 kPa. By flowing the chlorine gas into etching chamber 1A in this way at a predetermined flow rate for a predetermined period of time, the following reaction takes place in main surface 10b of seed substrate 10: SiC+Cl₂→SiCl₄. Accordingly, silicon (Si) atoms forming the silicon carbide of seed substrate 10 are selectively removed from an etching region 10c including main surface 10b of seed substrate 10 as shown in FIG. 4, with the result that carbon (C) atoms forming seed substrate 10 remain.

Next, as step (S22), a nitrogen substituting step is performed. In this step (S22), referring to FIG. 3, after vacuuming etching chamber 1A, nitrogen (N₂) gas, which is an inert gas, is introduced into etching chamber 1A via the gas inlet and is exhausted via the gas outlet. Accordingly, the chlorine gas and silicon tetrachloride (SiCl₄) gas remaining in etching chamber 1A after step (S21) is substituted with the nitrogen gas. It should be noted that the inert gas introduced into etching chamber 1A is not limited to the nitrogen (N₂) gas, and may be a noble gas such as argon (Ar), for example.

Next, as step (S23), a second etching step is performed. In this step (S40), first, with the temperature in etching chamber 1A being maintained at not less than 800° C. and not more than 1100° C., oxygen (O₂) gas, which is an oxidizing gas, is introduced into etching chamber 1A via the gas inlet and is exhausted via the gas outlet. Etching chamber 1A is set to have a pressure of not less than 1 Pa and less than 100 kPa. By flowing the oxygen gas into etching chamber 1A in this way at a predetermined flow rate for a predetermined period of time, the following reaction takes place in etching region 10c of seed substrate 10: SiC+SiC→CO₂. Accordingly, carbon atoms forming the silicon carbide of seed substrate 10 are removed from etching region 10c from which the silicon atoms have been removed. As a result, as shown in FIG. 5, etching region 10c is removed from seed substrate 10, thereby forming a crystal growth surface 10d. Further, the oxidizing gas is not limited to the oxygen gas, and may be ozone (O₃) gas or hydrogen (H₂) gas, for example. By performing the above-described steps (S21) to (S23) in this way, main surface 10b of seed substrate 10 is etched, thus completing step (S20).

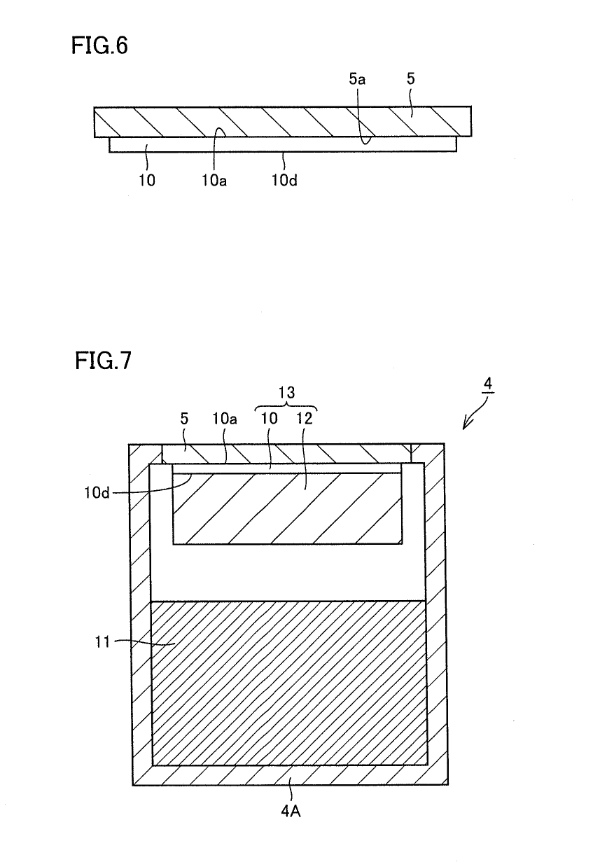

Next, as a step (S30), a seed substrate adhering step is performed. In this step (S30), referring to FIG. 7, a cover member 5 is first detached from a crucible 4 made of carbon. Next, referring to FIG. 6, seed substrate 10 is adhered to cover member 5 such that main surface 10a faces a supporting surface 5a of cover member 5. Seed substrate 10 is adhered to cover member 5 using, for example, a carbon adhesive agent.

Next, as a step (S40), a single crystal growth step is performed. In this step (S40), an ingot 13 is obtained by growing a silicon carbide single crystal film 12 on crystal growth surface 10d of seed substrate 10 in the following manner. Referring to FIG. 7, a powdery silicon carbide source material 11 is first contained in a crucible main body 4A. Next, cover member 5 thus having seed substrate 10 adhered thereon is placed onto crucible main body 4A. In this way, seed substrate 10 is placed in crucible 4 such that crystal growth surface 10d faces silicon carbide source material 11.

Next, while vacuuming crucible 4, temperature therein is increased to a predetermined temperature. Next, an inert gas such as argon (Ar) is introduced into crucible 4. Next, the temperature in crucible 4 is increased to a temperature at which a silicon carbide single crystal is grown (not less than 2000° C. and not more than 2400° C.). Next, crucible 4 is vacuumed to reduce the pressure to a predetermined pressure to start growth of silicon carbide single crystal film 12. In this way, silicon carbide single crystal film 12 is grown on crystal growth surface 10d of seed substrate 10, thus obtaining ingot 13.

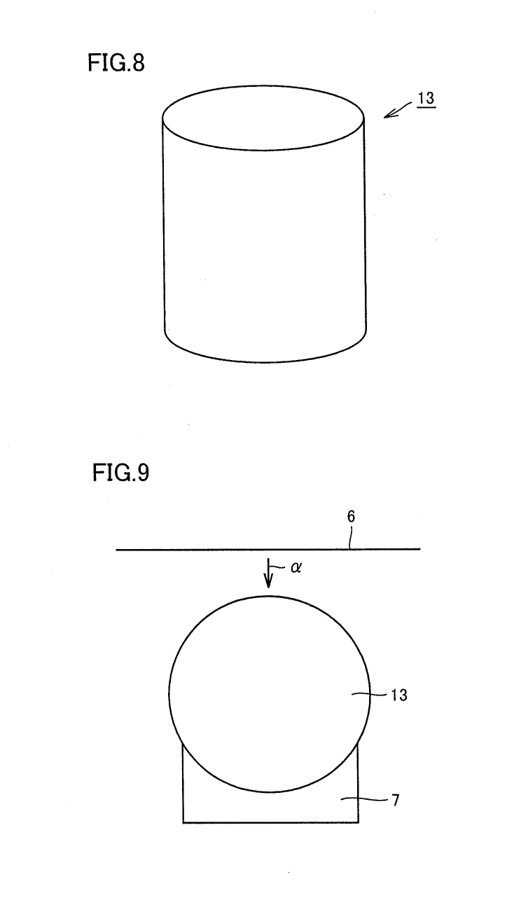

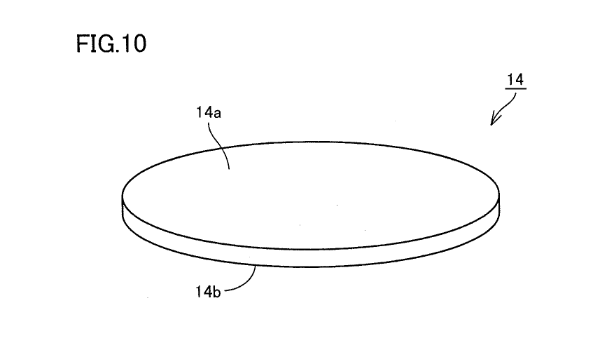

Next, as a step (S50), a cutting step is performed. In this step (S50), referring to FIG. 8 and FIG. 9, ingot 13 is first placed such that a portion of a side surface thereof is supported by a holder 7. Next, a wire 6 is moved to travel in a direction along the diameter direction of ingot 13 and approaches ingot 13 with wire 6 itself being along a cutting direction a perpendicular to the travel direction so as to bring wire 6 into contact with ingot 13. Then, by continuously advancing wire 6 with wire 6 itself being along cutting direction α, ingot 13 is cut. Accordingly, a silicon carbide substrate 14 shown in FIG. 10 is obtained.

Next, a polishing step is performed as a step (S60). In this step (S60), referring to FIG. 10, main surfaces 14a, 14b of silicon carbide substrate 14 are polished using diamond abrasive grains or the like. Next, as step (S70), an evaluation examination step is performed. In this step (S70), quality of silicon carbide substrate 14 is examined in terms of crystal defects and the like. By performing the above-described steps (S10) to (S70), silicon carbide substrate 14 is manufactured, thus completing the method for manufacturing the silicon carbide substrate in the present embodiment.

As described above, in the method for manufacturing the silicon carbide substrate in the present embodiment, main surface 10b of seed substrate 10 is etched through the step including: the first etching step (S21) of removing the silicon atoms from etching region 10c including main surface 10b of seed substrate 10; and the second etching step (S23) of removing the carbon atoms from etching region 10c from which the silicon atoms have been removed. Accordingly, an amount of etching seed substrate 10 is increased as compared with a conventional method for manufacturing a silicon carbide substrate, whereby the damage layer in main surface 10b of seed substrate 10 can be sufficiently removed even when the damage layer is thick. As a result, crystal defects can be suppressed from occurring in silicon carbide single crystal film 12 due to the damage layer. Thus, according to the method for manufacturing the silicon carbide substrate in the present embodiment, a silicon carbide substrate having high quality can be manufactured.

Further, in the present embodiment, the silicon atoms may be removed from etching region 10c by the chlorine gas in step (S21), but the present invention is not limited to this. For example, the silicon atoms may be removed from etching region 10c by hydrogen chloride (HCl) gas. As such, in step (S21), the chlorine gas or hydrogen chloride gas suitable for etching of seed substrate 10 made of silicon carbide can be employed suitably as the etching gas.

Further, as described above, in the present embodiment, step (S22) of substituting the chlorine gas with the nitrogen gas may be performed after step (S21) and before step (S23). Accordingly, silicon tetrachloride gas generated in step (S21) can be suppressed from reacting with oxygen gas and generating silicon dioxide (SiO₂).

Further, in the present embodiment, in step (S50), silicon carbide substrate 14 having a diameter of 2 inches or more may be obtained. Thus, the method for manufacturing the silicon carbide substrate in the present embodiment can be suitably employed in manufacturing of a silicon carbide substrate having a large diameter.

Further, as described above, in the present embodiment, in step (S20), main surface 10b of seed substrate 10 may be etched at a temperature of not less than 800° C. and not more than 1100° C. Thus, in step (S20), there can be employed a temperature condition under which main surface 10b of seed substrate 10 can be effectively etched.

Further, as described above, in the present embodiment, in step (S20), main surface 10b of seed substrate 10 may be etched at a pressure of not less than 1 Pa and less than 100 kPa. Thus, in step (S20), there can be employed a pressure condition under which main surface 10b of seed substrate 10 can be effectively etched.

Further, in the present embodiment, in step (S50), silicon carbide substrate 14 can be obtained which has a dislocation density of 1×10⁴cm ⁻² or less. In this way, a semiconductor device having higher quality can be manufactured using silicon carbide substrate 14.

Further, in the present embodiment, in step (S20), etching region 10c to be removed from seed substrate 10 has a thickness adjustable depending on etching conditions such as gas flow rate, process time, temperature, and pressure. Hence, in step (S20), it is preferable to appropriately select etching conditions so as to sufficiently remove the damage layer in main surface 10b of seed substrate 10. For example, in the case where only grinding of main surface 10b of seed substrate 10 is performed in step (S10), etching region 10c preferably has a thickness of not less than 10 μm or not less than 20 μm. Further, in the case where polishing is additionally performed by means of mechanical polishing, etching region 10c preferably has a thickness of not less than 5 μm or not less than 10 μm. Further, when performing the polishing by means of CMP, etching region 10c preferably has a thickness of not less than 1 μm.

### Example

An experiment was conducted to confirm the effect of the present invention with regard to quality of the silicon carbide substrate. First, a seed substrate having a diameter of 2 inches and made of silicon carbide was prepared. Next, the seed substrate thus prepared was placed in an etching chamber of a reaction tube such that its main surface to be etched faced upward. The etching chamber had a volume of 14 L. Next, the etching chamber was vacuumed to reduce pressure to 50 Pa. Next, while maintaining the vacuum state in the etching chamber, temperature therein was increased to 1000° C. Next, chlorine gas was introduced into the etching chamber. The chlorine gas was introduced at a flow rate of 0.3 L/min for 30 minutes. Next, the etching chamber was vacuumed and the gas in the etching chamber was substituted with nitrogen gas. Next, oxygen gas was introduced into the etching chamber. The oxygen gas was introduced at a flow rate of 2 L/min for 5 minutes. Then, a change in the thickness of the seed substrate before and after the etching was inspected. Next, a silicon carbide single crystal film was foamed on the crystal growth surface of the seed substrate, thereby producing an ingot. Next, the ingot was cut, thereby obtaining a silicon carbide substrate. Then, dislocation density in the silicon carbide substrate thus obtained was inspected. Meanwhile, as a comparative example, a crystal growth surface of a seed substrate was polished by means of CMP and dislocation density of a silicon carbide substrate obtained in the same manner as in the above-described example was inspected in the same manner.

The following describes a result of the experiment. First, the change in the thickness of the seed substrate before and after the etching was 20 μm. Thus, in the method for manufacturing the silicon carbide substrate in the present invention, it was confirmed that the amount of etching the seed substrate was more increased. Further, the silicon carbide substrate in the above-described comparative example had a dislocation density of 35000 cm ⁻², whereas the silicon carbide substrate in the above-described example had a dislocation density of 10000 cm⁻². In this way, according to the method for manufacturing the silicon carbide substrate in the present invention, it was confirmed that a silicon carbide substrate having high quality can be manufactured by sufficiently removing the damage layer in the main surface of the seed substrate.

The method for manufacturing the silicon carbide substrate in the present invention can be particularly advantageously applied to a method for manufacturing a silicon carbide substrate, which is required to manufacture a silicon carbide substrate having high quality.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method for manufacturing a silicon carbide substrate, comprising the steps of:
preparing a seed substrate made of silicon carbide;
etching one main surface of said seed substrate prepared;
obtaining an ingot by growing a single crystal film, which is made of silicon carbide, on a crystal growth surface formed by etching said main surface of said seed substrate; and
obtaining a silicon carbide substrate by cutting said ingot, the step of etching said seed substrate including:
a first etching step of removing silicon atoms, which form said silicon carbide, from an etching region using a gas including halogen atoms, said etching region being a region including said main surface of said seed substrate; and
a second etching step of removing carbon atoms, which form said silicon carbide, from said etching region from which the silicon atoms have been removed, using an oxidizing gas.

2. The method for manufacturing the silicon carbide substrate according to claim 1, wherein
in said first etching step, the silicon atoms forming said silicon carbide are removed while the carbon atoms forming said silicon carbide remain in said etching region.

3. The method for manufacturing the silicon carbide substrate according to claim 1, wherein
in said first etching step, the silicon atoms forming said silicon carbide are removed from said etching region using chlorine gas or hydrogen chloride gas.

4. The method for manufacturing the silicon carbide substrate according to claim 1, further comprising the step of substituting the gas including said halogen atoms with an inert gas, after said first etching step and before said second etching step.

5. The method for manufacturing the silicon carbide substrate according to claim 1, wherein
said silicon carbide substrate obtained in the step of obtaining said silicon carbide substrate has a diameter of 2 inches or more.

6. The method for manufacturing the silicon carbide substrate according to claim 1, wherein
in the step of etching said seed substrate, said main surface of said seed substrate is etched at a temperature of not less than 800° C. and not more than 1100° C.

7. The method for manufacturing the silicon carbide substrate according to claim 1, wherein
in the step of etching said seed substrate, said main surface of said seed substrate is etched at a pressure of not less than 1 Pa and less than 100 kPa.

8. The method for manufacturing the silicon carbide substrate according to claim 1, wherein
said silicon carbide substrate obtained in the step of obtaining said silicon carbide substrate has a dislocation density of 1×10⁴cm ⁻² or less.
